(19) United States
(12) Patent Application Publication
(10) Pub. No.: US 2009/0068851 A1
(43) Pub. Date: Mar. 12, 2009

(54) SUSCEPTOR, MANUFACTURING APPARATUS FOR SEMICONDUCTOR DEVICE AND MANUFACTURING METHOD FOR SEMICONDUCTOR DEVICE

(76) Inventors: Hironobu Hirata, Mishima-shi (JP); Yoshikazu Moriyama, Izu-shi (JP); Masayoshi Yajima, Kanagawa-ken (JP); Shinichi Mitani, Numazu-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/207,754

(22) Filed: Sep. 10, 2008

(30) Foreign Application Priority Data
Sep. 11, 2007 (JP) 2007-235685

(51) Int. Cl. H01L 21/31; C23C 14/50

(52) U.S. Cl. 438/778; 118/730; 257/E21.24

(57) ABSTRACT

A susceptor of the present invention includes an inner susceptor having a diameter smaller than a diameter of a wafer w and a protruding part for placing the wafer w on a surface thereof, and an outer susceptor having an opening in the central portion thereof, a first step section for placing the inner susceptor so as to block the opening and a second step section provided above the first step section for placing the wafer.

### CROSS-REFERENCE TO RELATED APPLICATION

This application is based upon and claims the benefit of priority from the prior Japanese Patent Application No. 2007-235685 filed on Sep. 11, 2007, the entire contents of which are incorporated herein by reference.

### BACKGROUND OF THE INVENTION

1. Field of the Invention

The present invention relates to a susceptor used for film formation by, for example, supplying reaction gas to a front face of a semiconductor wafer while heating the semiconductor wafer from its rear face, and for holding the semiconductor wafer, a manufacturing apparatus for a semiconductor device and a manufacturing method for a semiconductor device.

2. Description of the Related Art

For a chemical vapor deposition (CVD) apparatus, which is used to form an epitaxial film in a semiconductor manufacturing process, there has been generally used a rear face heating method, in which a heat source and a rotating mechanism are provided under the wafer to enable uniform supply of process gas from the above.

In recent years, for further microscopic and higher performance of semiconductor devices, metal pollution level in a film formation process is required to satisfy high standard. In such a rear face heating method, a heat source and a rotating mechanism is provided under a wafer and the wafer is not completely isolated from the heat source and the rotating mechanism. Therefore there may occur a problem of wafer pollution caused by diffusion or migration of a metallic atom.

Usually, a wafer is hold by a susceptor within a film formation apparatus (reaction chamber) and moved upwardly by push-up pins penetrating through pin holes formed in the susceptor during transportation. Therefore, there is a problem of difficult blocking of wafer pollution particularly from the pin hole.

On the other hand, for example, Japanese Patent Application Laid-Open No. 2000-43302 ([0019] to [0022], [0036], FIG. 1 and others) has proposed a susceptor structure without any pin hole in order to make the wafer temperature uniform. However, the susceptor structure without any pin hole generates an aerial layer under a wafer when the wafer is placed and the wafer floats up, thus it is difficult to hold the wafer stably. When the wafer is heated and rotated and process gas is supplied thereon to form a film, uniform film formation is difficult under such an instable state.

Also, uniform film formation requires rotation of the wafer at a high speed, however the wafer may be out of placement position of the susceptor at a high speed under such an instable state. Therefore there is a problem of difficulty in uniform film formation due to high speed rotation.

### SUMMARY OF THE INVENTION

A susceptor according to an aspect of the present invention includes an inner susceptor having a diameter smaller than a diameter of the wafer and a protruding part for placing the wafer on a surface thereof, and an outer susceptor having an opening in the central portion thereof, a first step section for placing the inner susceptor so as to block the opening and a second step section provided above the first step section for placing the wafer.

A manufacturing apparatus for a semiconductor device according to an aspect of the present invention includes a reaction chamber for loading a wafer, a gas supply mechanism for supplying process gas to the reaction chamber, a gas exhaust mechanism for exhausting the process gas from the reaction chamber, an inner susceptor having a diameter smaller than a diameter of the wafer and a protruding part for placing the wafer on a surface thereof, an outer susceptor having an opening in the central portion thereof, a first step section for placing the inner susceptor so as to block the opening and a second step section provided above the first step section for placing the wafer, a heater for heating the wafer from bottom of the inner susceptor and the outer susceptor, a rotating mechanism for rotating the wafer, and a vertical drive mechanism for moving the inner susceptor upwardly and downwardly.

A manufacturing method for a semiconductor device according to an aspect of the present invention includes loading a wafer into a reaction chamber, raising an inner susceptor, which is installed in the reaction chamber, has a diameter smaller than a diameter of the wafer and has a protruding part on a surface thereof, and placing the wafer on the protruding parts of the inner susceptor, lowering the inner susceptor, placing the inner susceptor on a first step section of an outer susceptor having an opening in the central portion thereof so as to block the opening and holding the wafer on a second step section provided above the first step section of the outer susceptor; heating the wafer through the inner susceptor and the outer susceptor, rotating the wafer, and supplying process gas to the wafer.

It is to be understood that both the forgoing general description and the following detailed description are exemplary and explanatory only and are not restrictive of the invention, as claimed.

### BRIEF DESCRIPTION OF THE DRAWINGS

The accompanying drawings, which is incorporated in and constitute a part of this specification, illustrates an embodiment of the invention and together with the description, serve to explain the principles of the invention.

FIG. 1 is a sectional view of a susceptor according to an embodiment of the present invention;

FIG. 2 is a sectional view of an inner susceptor according to an embodiment of the present invention;

FIG. 3 is a sectional view of an outer susceptor according to an embodiment of the present invention;

FIG. 4 is a sectional view of a manufacturing apparatus for semiconductor device according to an embodiment of the present invention;

FIG. 5 is a sectional view of a manufacturing apparatus for semiconductor device according to an embodiment of the present invention;

FIG. 6 is a sectional view of a susceptor according to an embodiment of the present invention; and

FIG. 7 is a sectional view of an inner susceptor according to an embodiment of the present invention.

### DETAILED DESCRIPTION OF THE EMBODIMENTS

Reference will now be made in detail to the present embodiment of the invention, an example of which is illustrated in the accompanying drawing. Wherever possible, the same reference numbers will be used throughout the drawing to refer to the same or like parts.

Referring to the accompanying drawings, an embodiment of the present invention will be described below.

### First Embodiment

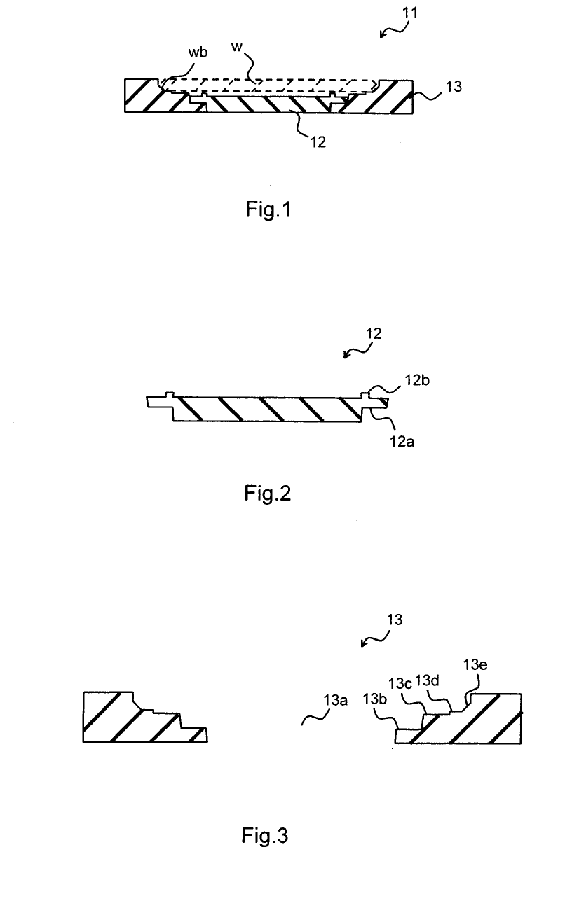

FIG. 1 illustrates a sectional view of a susceptor of the present embodiment. As illustrated, a susceptor 11 includes an inner susceptor 12, and an outer susceptor 13 separatable from the inner susceptor 12.

As illustrated in FIG. 2, the inner susceptor 12 has a smaller diameter than that of a wafer w to be placed and has a step section 12a at an edge portion. On the top face of the inner susceptor 12, for example, four dot-shaped protruding parts 12b are formed at approximately equal intervals on an identical circumference to place the wafer w.

On the outer susceptor 13, an opening 13a is formed in the central portion thereof and, at the edge portion of the opening 13a, step sections 13b, 13c, 13d are formed, as illustrated in FIG. 3. On the lowest step section 13b, the inner susceptor 12 is placed so as to block the opening 13a. By the middle step section 13c, a micro gap of, for example, approximately 0.2 mm is formed between the middle step section 13c and the wafer w, and the wafer is placed on the uppermost step section 13d. A taper 13e is formed at a portion of the step section 13d, on which a bevel portion w_{b} of the wafer w is placed, so as to have an approximately equal angle to a bevel taper angle of, for example, 22 degrees.

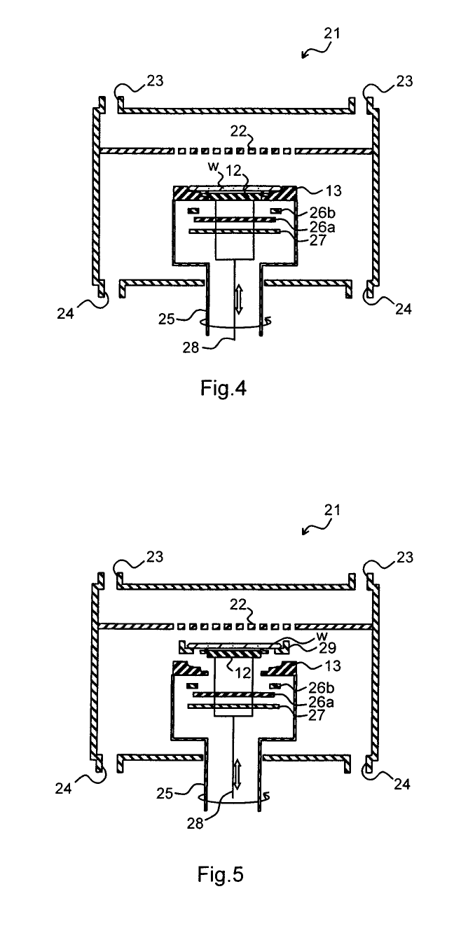

Such a susceptor 11 is installed, for example, in a manufacturing apparatus for a semiconductor device illustrated in FIG. 4. As illustrated in FIG. 4, a reaction chamber 21, in which the wafer w is subjected to film formation, is provided with a gas supply port 23 connected to a gas supply mechanism for supplying process gas onto the wafer w from above the reaction chamber 21 through a rectifying plate 22 and a gas exhaust port 24 connected to a gas exhaust mechanism for exhausting process gas from bottom of the reaction chamber 21.

Under the reaction chamber 21, there is a drive mechanism (not illustrated) outside the reaction chamber 21 and a rotating mechanism 25 for rotating the wafer w is provided. The rotating mechanism 25 is connected to an outer-periphery portion of the outer susceptor 13 of the susceptor 11 structured as described above.

Under the susceptor 11, an in-heater 26a for heating the wafer w is provided and, between the susceptor 11 and the in-heater 26a, an out-heater 26b for heating the peripheral edge of the wafer w is provided. The in-heater 26a and the out-heater 26b are controlled by a temperature control mechanism (not illustrated), based on a wafer temperature measured by a temperature measurement mechanism (not illustrated). Under the in-heater 26a, a disc-shaped reflector 27 is provided. Push-up pins 28 for vertically moving the inner susceptor 12 are provided so as to penetrate through the in-heater 26a and the reflector 27.

Using such a manufacturing apparatus for semiconductor device, for example, an Si epitaxial film is formed on the wafer w. First, as illustrated in FIG. 5, for example, an 8-inch wafer w is hold by a transfer arm 29 at the outer periphery portion and is loaded into the reaction chamber 21. By the push-up pin 28, the inner susceptor 12 is raised. At this time, the wafer w is hold by the transfer arm 29 outside the inner susceptor 12 and thus, the wafer w is placed on the inner susceptor 12 when the inner susceptor 12 is raised. Then, the inner susceptor 12 is lowered by a push-up pin 28 so that the wafer w and the inner susceptor 12 are placed on the outer susceptor 13.

At this time, the wafer w is placed on the protruding parts 12b of the inner susceptor 12 to form a gap between the bottom of the wafer w and the inner susceptor 12. The step section 12a of the inner susceptor is placed on the step section 13b of the outer susceptor 13, and the wafer w is placed on the step section 13d having a micro gap with the step section 13c.

Next, based on the temperature of the wafer w measured by the temperature measurement mechanism (not illustrated) temperatures of the in-heater 26a and the out-heater 26b are appropriately controlled, for example, within a range of 1400 to 1500° C. by a temperature control mechanism (not illustrated) to control the temperature of the wafer w uniformly in the surface, for example, to be 1100° C. In addition, the wafer w is rotated, for example, at 900 rpm by the rotating mechanism 25.

From the gas supply port 23, for example, process gas including carrier gas: H₂ of 20 to 100 SLM, film formation gas: SiHCl₃ of 50 sccm to 6 SLM, dopant gas: trace of B2H6, PH₃: small amount, is introduced onto the rectifying plate 22 and supplied onto the wafer w in a rectifying state. At this time, the pressure in the reaction chamber 21 is controlled within the range of, for example, 1333 Pa (10 Torr) to ordinaly pressure, by adjusting valves at the gas supply port 23 and the gas exhaust port 24. Accordingly, respective conditions are controlled and an epitaxial film is formed on the wafer w.

On the epitaxial film formed in this way, Fe diffusion length was measured by the Surface Photovoltage (SPV). Measurement result shows that the diffusion length was sufficient (for example, 400 μm) and the metallic pollution was inhibited in the case of using a susceptor without any pin holes according to the present invention on the contrary of the insufficient diffusion length measured in the case of using a conventional susceptor having pin holes.

Since a gap is generated by the protruding parts 12b between the bottom of the wafer and the inner susceptor, the wafer w can be hold on the susceptor 11 in a stable state. Further, the step section 13d has a taper 13e having an angle which is approximately equal to a bevel taper angle. Accordingly, by placing a bevel portion wb of the wafer w on the taper 13e, the wafer w can be hold more stably.

Since a micro gap can be generated between the wafer w and the outer susceptor 13 by the step section 13c, the wafer w can be stably hold on the outer periphery of the wafer w even if a warp or the like occurs in the wafer w. In addition, the amount of heat conducted to the wafer is always kept constant, thus always keeping temperature distribution in the wafer surface constant.

Hence, a uniform epitaxial film having variation in film thickness of, for example, 0.5% or less can be formed on the wafer.

In forming a semiconductor device through an element forming process and an element separating process, variation in element characteristics is inhibited, thereby improving yield and reliability. Application particularly to a power semiconductor device such as power MOSFET and IGBT (insulated gate bipolar transistor), which requires a film thickness growth of several 10 μm to 100 μm, to form an N-type base region, a P-type base region or an insurable region, is preferable. By applying to an epitaxial formation process of the power semiconductor device, excellent element characteristics can be obtained.

In the present embodiment, the step sections are formed on the inner susceptor 12 and the outer susceptor 13, respectively, as illustrated in FIG. 1. The number of step sections and a level difference therebetween may be designed as needed. In addition, each of the step sections may be tapered as needed.

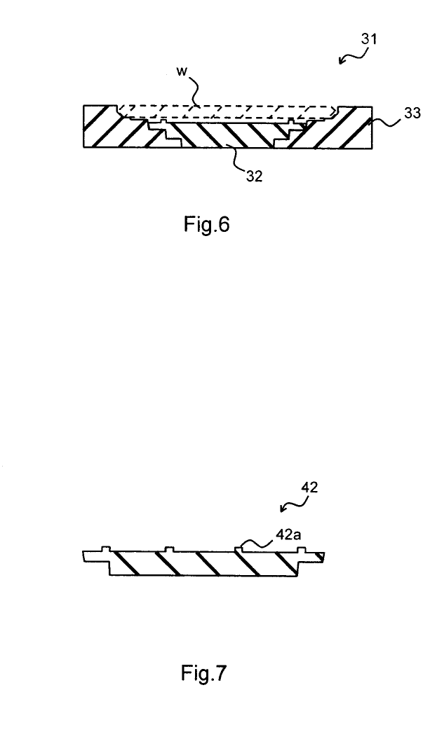

For example, as illustrated in FIG. 6, a joint of the inner susceptor 32 and the outer susceptor 33 in the susceptor 31 may respectively have two steps. By forming multiple steps in this way, passage of a pollution substance from the rear side of the susceptor can be prevented, thus attaining more highly effective restraint of metal pollution of a wafer.

Forming the step section 12a on the inner susceptor 12 is effective in restraining metal pollution, but the formation is not necessary. The rear face of the inner susceptor 12 may be formed in flat and may be placed on the step section 13b of the outer susceptor 13.

Four dot-shaped portions are provided as the protruding parts 12b formed on the top face of the inner susceptor 12, but the shape and location thereof are not particularly limited as long as the wafer w can be hold horizontally. For example, to minimize a contact area with the wafer w, it is preferable to hold the wafer w by three dot-shaped protruding parts. Alternatively, a ring-shaped protruding part having a cut (discontinuous portion) at one or more positions is also applicable.

The protruding parts are not always required to be located near the outer periphery of the inner susceptor 12. As illustrated in FIG. 7, the protruding parts 42a of the inner susceptor 42 may be arranged at approximately equal intervals on the identical circumference of the central section thereof. This arrangement enables to hold the wafer more stably.

In the present embodiment, a case where formation of a Si single-crystal layer (epitaxial growth layer) has been described, but the present embodiment is also applicable to forming a polysilicon layer. In addition, the present embodiment is also applicable to other compound semiconductors such as GaAs layer, GaAlAs and InGaAs. Further, the present embodiment is also applicable to forming a SiO₂ film or Si₃N₄ film. To form SiO₂ film, N₂, O₂ or Ar gas is supplied. To form Si₃N₄ film, NH₃, N₂, O₂ or Ar gas in addition to monosilane (SiH₄) is supplied.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A susceptor for holding a wafer, comprising:
an inner susceptor having a diameter smaller than a diameter of the wafer and a protruding part for placing the wafer on a surface of the inner susceptor; and
an outer susceptor having an opening in a central portion of the outer susceptor, a first step section for holding the inner susceptor to block the opening and a second step section provided above the first step section for placing the wafer.

2. The susceptor according to claim 1, wherein the protruding part and one or more other protruding part are formed on an identical circumference of the inner susceptor.

3. The susceptor according to claim 1, wherein the second step section has a taper at a portion, a bevel portion of the wafer is placed on the portion.

4. The susceptor according to claim 1, wherein the first step section includes a plurality of step sections.

5. The susceptor according to claim 4, wherein the inner susceptor has a plurality of step sections corresponding to the plurality of step sections.

6. The susceptor according to claim 1, wherein the outer susceptor has a third step section between the first step section and the second step section.

7. A manufacturing apparatus for a semiconductor device, comprising:
a reaction chamber for loading a wafer;
a gas supply mechanism for supplying process gas to the reaction chamber;
a gas exhaust mechanism for exhausting the process gas from the reaction chamber;
an inner susceptor having a diameter smaller than a diameter of the wafer and a protruding part for placing the wafer on a surface of the inner susceptor;
an outer susceptor having an opening in the central portion of the outer susceptor, a first step section for placing the inner susceptor to block the opening and a second step section provided above the first step section for holding the wafer;
a heater for heating the wafer from bottom of the inner susceptor and the outer susceptor;
a rotating mechanism for rotating the wafer; and
a vertical drive mechanism for moving the inner susceptor upwardly and downwardly.

8. The manufacturing apparatus for a semiconductor device according to claim 7, wherein the protruding part and one or more other protruding part are formed at approximately equal intervals on an identical circumference.

9. The manufacturing apparatus for a semiconductor device according to claim 7, wherein the second step section has a taper at a portion a bevel portion of the wafer is placed on the portion.

10. The manufacturing apparatus for a semiconductor device according to claim 7, wherein the first step section includes a plurality of step sections.

11. The manufacturing apparatus for a semiconductor device according to claim 7, wherein the inner susceptor has a plurality of step sections corresponding to the plurality of step sections.

12. The manufacturing apparatus for a semiconductor device according to claim 7, wherein the outer susceptor has a third step section between the first step section and the second step section.

13. The manufacturing apparatus for a semiconductor device according to claim 7, wherein the rotating mechanism is rotatable at a speed of 900 rpm or higher.

14. The manufacturing apparatus for a semiconductor device according to claim 7, wherein the vertical drive mechanism is push-up pins penetrating through the heater.

15. A manufacturing method for a semiconductor device, comprising:
loading a wafer into a reaction chamber;
raising an inner susceptor installed in the reaction chamber, the inner susceptor having a diameter smaller than a diameter of the wafer and a protruding part on a surface of the inner susceptor, and placing the wafer on the protruding parts of the inner susceptor;
lowering the inner susceptor, placing the inner susceptor on a first step section of an outer susceptor having an opening in the central portion of the outer susceptor to block the opening and placing the wafer on a second step section provided above the first step section of the outer susceptor;
heating the wafer through the inner susceptor and the outer susceptor;
rotating the wafer; and
supplying process gas to the wafer.

16. The manufacturing method for a semiconductor device according to claim 15, further comprising supporting an inner susceptor by a pushing-up pin for raising the inner susceptor or lowering the inner susceptor.

17. The manufacturing method for a semiconductor device according to claim 15, wherein the second step section has a taper and a bevel portion of the wafer is placed on the taper when the wafer is hold on the second step section.

18. The manufacturing method for a semiconductor device according to claim 15, wherein the outer susceptor has a third step section between the first step section and the second step section and a micro gap is formed between the wafer rear face and the third step section when the wafer is placed on the second step section.

19. The manufacturing method for a semiconductor device according to claim 15, wherein the wafer is rotated at a speed of 900 rpm or higher.

20. The manufacturing method for a semiconductor device according to claim 15, wherein an epitaxial film having a thickness of 10 μm or more is formed on the wafer.
